(19) United States
(12) Patent Application Publication
(10) Pub. No.: US 2025/0270729 A1
(43) Pub. Date: Aug. 28, 2025

(54) PLATING APPARATUS AND CLEANING METHOD FOR CLEANING SUBSTRATE HOLDER

(71) Applicant: EBARA CORPORATION, Tokyo (JP)

(72) Inventor: Gaku YAMASAKI, Tokyo (JP)

(21) Appl. No.: 18/858,289

(22) PCT Filed: Jan. 6, 2023
(86) PCT No.: PCT/JP2023/000133

§ 371 Date: Oct. 18, 2024

(51) Int. Cl. C25D 17/06; C25D 21/08

(52) U.S. Cl. CPC C25D 17/06; C25D 21/08

(57) ABSTRACT

To remove cleaning liquid remaining after cleaning of a substrate holder in a plating apparatus. A plating apparatus includes a substrate holder configured to hold a substrate and including an electrical contact for supplying power to the substrate, a holder cleaning tank for cleaning the substrate holder when the substrate holder is not holding the substrate, a holder drying tank for drying the substrate holder cleaned in the holder cleaning tank, and a conveyance device for conveying the substrate holder between the holder cleaning tank and the holder drying tank.

### TECHNICAL FIELD

The present application relates to a plating apparatus and a cleaning method for cleaning a substrate holder.

### BACKGROUND ART

Conventionally, a device configured to vertically insert a substrate held by a substrate holder into a plating tank housing plating solution and perform electrolytic plating has been known (refer to PTL 1, for example). In addition, a device configured to horizontally place a substrate held by a substrate holder and perform electrolytic plating has been known (refer to PTL 2, for example). A substrate holder used in such a plating apparatus includes a seal ring holder with a seal that seals the surface of a substrate, and a base plate. The substrate holder seals the surface of the substrate to form a space that plating solution does not enter. The substrate holder includes, in the space, an electrical contact for contacting the surface of the substrate and flowing current to the substrate.

Such a substrate holder prevents plating solution from entering the above-described space by appropriately sealing the surface of the substrate. However, the plating solution infrequently enters the above-described space due to an abnormality of the seal or the like. When the plating solution enters the above-described space, the plating solution potentially contacts and corrodes the electrical contact. Thus, the electrical contact needs to be cleaned in a case where leakage has occurred to the substrate holder and the plating solution has contacted the electrical contact. After plating processing, the substrate is cleaned together with the substrate holder in a rinse module to wash away a residual plating solution having adhered to the substrate holder. Furthermore, as the substrate holder is repeatedly used, foreign objects adhere to the seal or the electrical contact in some cases. Thus, the seal and the electrical contact of the substrate holder are preferably periodically cleaned. In this context, a cleaning device configured to clean a sealing member and the like of the substrate holder has been known (refer to PTL 3).

### CITATION LIST

### Patent Literature

PTL 1: Japanese Patent No. 3979847
PTL 2: U.S. Patent Application Publication No. 2014/0318977
PTL 3: Japanese Patent Laid-open No. 2008-45179

### SUMMARY OF INVENTION

### Technical Problem

If cleaning liquid remains in the substrate holder after the substrate holder is cleaned in the cleaning device, the cleaning liquid results in insufficient sealing by the substrate holder and causes a contact failure to the electrical contact and the substrate. The above-described PTLs do not discuss measures for a residual cleaning liquid remaining in the substrate holder. Such a problem is not limited to a plating apparatus of a scheme in which the electrical contact and the substrate contact in the above-described space that plating solution does not enter, but cleaning liquid remaining in the substrate holder is preferably removed also in a scheme in which the electrical contact of the substrate holder is immersed in plating solution.

In view of the above-described circumstances, it is one objective of the present application to remove cleaning liquid remaining after cleaning of a substrate holder in a plating apparatus.

### Solution to Problem

According to an embodiment, a plating apparatus is proposed, and the plating apparatus includes a substrate holder configured to hold a substrate and including an electrical contact for supplying power to the substrate, a holder cleaning tank for cleaning the substrate holder when the substrate holder is not holding the substrate, a holder drying tank for drying the substrate holder cleaned in the holder cleaning tank, and a conveyance device for conveying the substrate holder between the holder cleaning tank and the holder drying tank.

According to another embodiment, a cleaning method for cleaning a substrate holder including an electrical contact for supplying power to a substrate in a plating apparatus is proposed, and the cleaning method includes a process of conveying the substrate holder holding no substrate to a cleaning tank by a conveyance device, a process of cleaning the substrate holder in the cleaning tank, a process of conveying the cleaned substrate holder from the cleaning tank to a drying tank, and a process of drying the substrate holder in the drying tank.

### BRIEF DESCRIPTION OF DRAWINGS

FIG. 1 is an entire disposition diagram of a plating apparatus in an embodiment of the present invention.

FIG. 2 is a front view schematically illustrating a substrate holder in the embodiment.

FIG. 3 is a cross-sectional view of the substrate holder illustrated in FIG. 2 when viewed in a direction of AA-AA, in which the substrate holder is locked.

FIG. 4 is a cross-sectional view of the substrate holder illustrated in FIG. 2 when viewed in the direction of AA-AA, in which the substrate holder is semi-locked.

FIG. 5 is a perspective view schematically illustrating a configuration overview of a holder cleaning module in the present embodiment.

FIG. 6 is a diagram schematically illustrating positions of cleaning liquid nozzles in the holder cleaning module illustrated in FIG. 5.

FIG. 7 is a diagram schematically illustrating a schematic configuration of a holder drying module in the present embodiment.

FIG. 8 is a front view of the holder drying module illustrated in FIG. 7.

FIG. 9 is a side cross-sectional view of the holder drying module illustrated in FIG. 7.

FIG. 10 is a sectional perspective view schematically illustrating a configuration of a holder drying tank and a heater mechanism in the present embodiment.

FIG. 11 is a diagram schematically illustrating a first example of a holder insertion port of the holder drying tank in the present embodiment.

FIG. 12 is a diagram schematically illustrating a second example of the holder insertion port of the holder drying tank in the present embodiment.

FIG. 13 is a flowchart illustrating an example of cleaning processing for the substrate holder in the plating apparatus in the present embodiment.

### DESCRIPTION OF EMBODIMENT

An embodiment of the present invention will be described below with reference to the accompanying drawings. However, the referred drawings are schematic diagrams.

Accordingly, for example, the size, position, and shape of any component illustrated may differ its size, position, and shape in an actual device. In the following description and drawings referred to in the following description, any part that can be configured in an identical manner is denoted by the same reference sign, and duplicate description thereof is omitted.

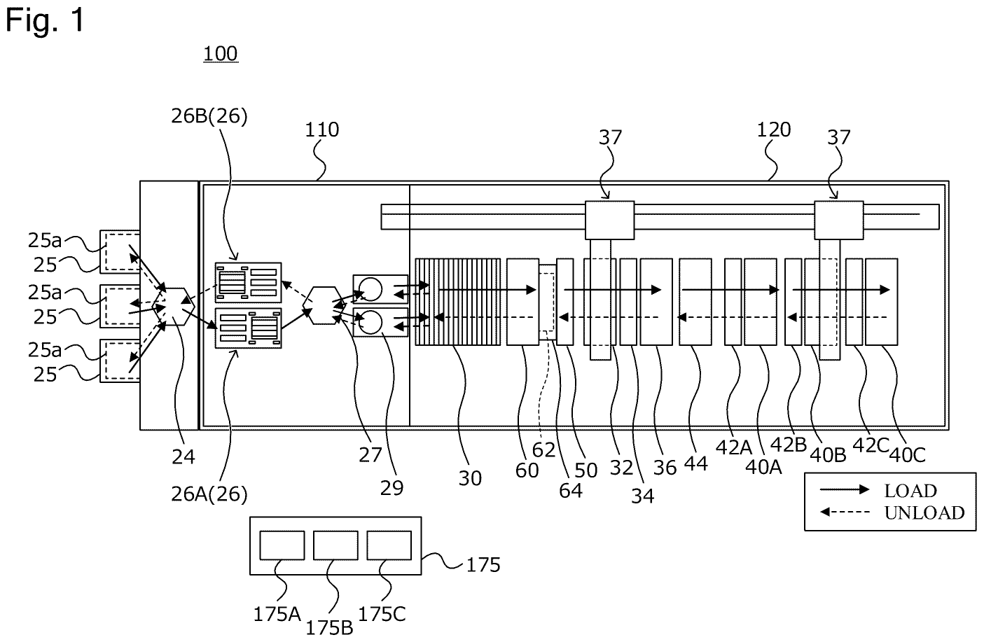

FIG. 1 is an entire disposition diagram of a plating apparatus in the embodiment of the present invention. A plating target object in the present embodiment is a substrate such as a semiconductor wafer. A substrate includes a quadrilateral substrate of a rectangle or a hexagon, and a circular substrate. As illustrated in FIG. 1, this plating apparatus 100 is roughly divided into a load port 110, in which a substrate is loaded onto a substrate holder (not illustrated in FIG. 1) or unloaded from the substrate holder, and a processing module 120, in which a substrate is processed.

The load port 110 includes a disposition adjustment mechanism 26, a conveyance robot 27, and a fixing station 29. As an example, the load port 110 in the present embodiment includes two disposition adjustment mechanisms 26 of a loading disposition adjustment mechanism 26A configured to handle a substrate before processing, and an unloading disposition adjustment mechanism 26B configured to handle a substrate after processing. Note that the disposition adjustment mechanisms 26 are not limited to the loading and unloading disposition adjustment mechanisms 26A and 26B but may be used without being distinguished as loading and unloading mechanisms, respectively. In the present embodiment, the load port 110 includes two fixing stations 29. The two fixing stations 29 are identical mechanisms, and one that is available (not handling a substrate) is used. Note that one or three or more disposition adjustment mechanisms 26 and fixing stations 29 may be provided in accordance with space in the plating apparatus 100.

Substrates are conveyed from a plurality (three in FIG. 1, as an example) of cassette tables 25 to a disposition adjustment mechanism 26 (the loading disposition adjustment mechanism 26A) through a robot 24. Each cassette table 25 includes a cassette 25a in which a substrate is housed. The cassette is, for example, a hoop. Each disposition adjustment mechanism 26 is configured to adjust (align) the position and orientation of a placed substrate. The conveyance robot 27 configured to convey a substrate between each disposition adjustment mechanism 26 and each fixing station 29 is disposed therebetween. The conveyance robot 27 is configured to convey a substrate between each disposition adjustment mechanism 26 and each fixing station 29. A stocker 30 for housing substrate holders is provided near the fixing stations 29.

The processing module 120 of the plating apparatus 100 includes the stocker 30, a holder drying tank 60 in a holder drying module, a holder cleaning tank 50 in a holder cleaning module, a pre-wet tank 32, a temporary placement table 34, a pre-soak tank 36, a blow tank 44, rinse tanks 42 (42A to 42C), and plating tanks 40 (40A to 40C) in a plating module.

In the stocker 30, the substrate holder is stored and temporarily placed. In the holder cleaning tank 50, the substrate holder is cleaned without holding a substrate. In the holder drying tank 60, the substrate holder cleaned in the holder cleaning tank 50 is dried. In the pre-wet tank 32, a substrate is immersed into deionized water. In the temporary placement table 34, the substrate holder is temporarily placed. In the pre-soak tank 36, an oxide film on the surface of a conductive layer such as a seed layer formed on the surface of the substrate is etched and removed. In the blow tank 44, liquid is removed from the substrate after cleaning. In the rinse tanks 42, the substrate after plating is cleaned in rinse solution together with the substrate holder. In the plating tanks 40, the substrate holder holding the substrate is housed and the substrate is immersed into plating solution held inside and subjected to plating such as copper plating on the surface of the substrate. The stocker 30, the holder drying tank 60, the holder cleaning tank 50, the pre-wet tank 32, the pre-soak tank 36, the blow tank 44, the rinse tanks 42, and the plating tanks 40 are disposed in the stated order, as an example. Although not limited, the plurality (three in FIG. 1, as an example) of plating tanks 40 are provided in the present embodiment, and the plurality of rinse tanks 42 are provided in accordance with the plating tanks 40A to 40C.

The plating apparatus 100 includes a conveyance device 37 positioned beside these instruments and configured to convey the substrate holder between the instruments, the conveyance device 37 employing, for example, a linear motor scheme. The conveyance device 37 is configured to convey the substrate holder between the fixing stations 29, the stocker 30, the holder drying tank 60, the holder cleaning tank 50, the pre-wet tank 32, the temporary placement table 34, the pre-soak tank 36, the blow tank 44, the rinse tanks 42, and the plating tanks 40.

The plating apparatus 100 includes a controller 175 configured to control each component described above. The controller 175 includes a memory 175B storing a predetermined program, a central processing unit (CPU) 175A configured to execute the program in the memory 175B, and a control module 175C that is achieved as the CPU 175A executes the program. A recording medium constituting the memory 175B may include one or a plurality of optional recording media such as a ROM, a RAM, a hard disk, a CD-ROM, a DVD-ROM, and a flexible disk. Examples of programs stored in the memory 175B include a program configured to control conveyance by the conveyance device 37 and a program configured to control plating processing in each plating tank 40. The controller 175 may be configured to perform communication with a non-illustrated higher-level controller that performs overall control of the plating apparatus 100 and other related devices and may be configured to communicate data with a database included in the higher-level controller.

An example of a series of plating processing by the plating apparatus 100 will be described below. First, the robot 24 takes a substrate out of a cassette 25a and conveys the substrate to a disposition adjustment mechanism 26. The disposition adjustment mechanism 26 aligns the position of substrate's orientation flat or notch in a predetermined direction. The conveyance robot 27 transfers the substrate, disposition of which is adjusted by the disposition adjustment mechanism 26, to the fixing station 29. In addition, the substrate holder is taken out of the stocker 30 to the fixing station 29 by the conveyance device 37, and the substrate is held by the substrate holder at the fixing station 29.

The substrate held by the substrate holder is conveyed to the pre-wet tank 32 by the conveyance device 37. In the pre-wet tank 32, the substrate held by the substrate holder is subjected to pre-wet processing. The conveyance device 37 conveys the substrate subjected to the pre-wet processing to the pre-soak tank 36. In the pre-soak tank 36, the substrate held by the substrate holder is subjected to pre-soak processing. The conveyance device 37 conveys the substrate subjected to the pre-soak processing to the plating tanks 40. In the plating tanks 40, the substrate held by the substrate holder is subjected to plating processing.

The conveyance device 37 conveys the substrate subjected to the plating processing to the rinse tanks 42. In the rinse tanks 42, the substrate held by the substrate holder is subjected to cleaning processing. The conveyance device 37 conveys the substrate subjected to the cleaning processing to the blow tank 44. In the blow tank 44, the substrate held by the substrate holder is subjected to drying processing. The conveyance device 37 conveys the substrate subjected to the drying processing to the fixing station 29. At the fixing station 29, the substrate is removed from the substrate holder. The conveyance robot 27 conveys the substrate from the fixing station 29 to the adjustment mechanism 28. Lastly, the robot 24 receives the substrate from the adjustment mechanism 28 and conveys the substrate to the cassette 25a. The substrate holder from which the substrate is removed is housed in the stocker 30 by the conveyance device 37.

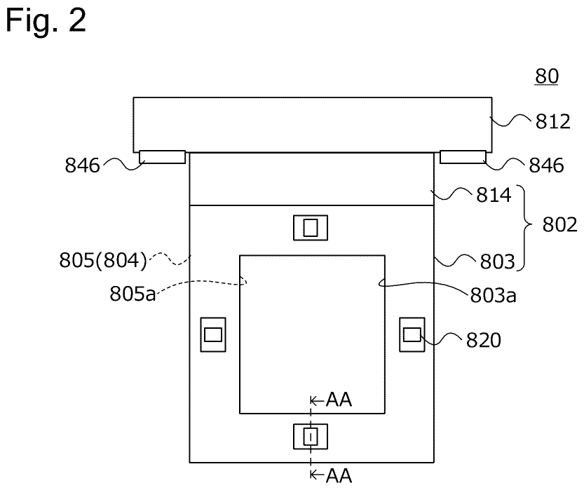

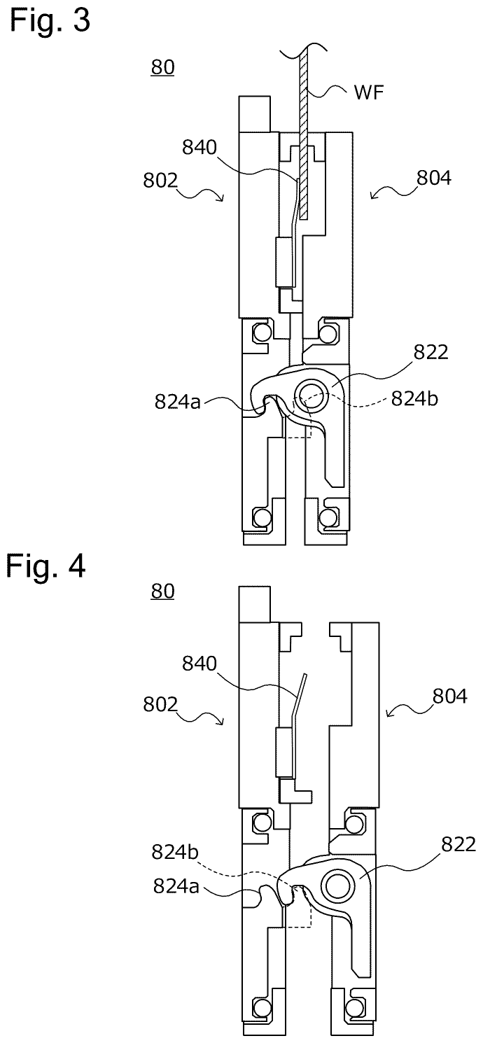

The substrate holder used in the plating apparatus 100 in the present embodiment will be described below. FIG. 2 is a front view schematically illustrating the substrate holder in the embodiment. FIGS. 3 and 4 are cross-sectional views of the substrate holder illustrated in FIG. 2 when viewed in a direction of AA-AA. The substrate holder 80 in the present embodiment is a member for holding a substrate by sandwiching the substrate between frames. Specifically, the substrate holder 80 includes a front frame 802 and a rear frame 804 and is configured to hold a substrate WF between the front frame 802 and the rear frame 804 by sandwiching. The front frame 802 and the rear frame 804 are clamped by at least one, preferably, a plurality of clampers 820.

An arm unit 812 is provided at an upper part of the front frame 802. As an example, the conveyance device 37 is configured to convey the substrate holder 80 by grasping the arm unit 812. A shoulder electrode 846 may be provided at a shoulder of the arm unit 812. In the example illustrated in FIG. 2, two shoulder electrodes 846 are provided at respective shoulders of the arm unit 812. Each shoulder electrode 846 is electrically connected through a non-illustrated conductive path (such as a wire or a bus bar) to an electrode (electrical contact 840; refer to FIG. 3) configured to contact the substrate WF. The plating apparatus 100 supplies electric power necessary for the plating processing to the substrate WF through the shoulder electrodes 846. In the above expression, “supplies electric power” may be interchanged with “applies voltage” or “flows current”. Note that although the arm unit 812 is connected to the front frame 802 in the present embodiment, the arm unit 812 may be connected to the rear frame 804 instead or in addition.

The front frame 802 and the rear frame 804 constitute a wiring storage unit 814. The wiring storage unit 814 is provided between a body 803 of the front frame 802 and the arm unit 812 and between a body 805 of the rear frame 804 and the arm unit 812. The wiring storage unit 814 is configured to define a space for storing wires for electrically connecting the shoulder electrodes 846 to the electrical contacts 840 connected to the substrate WF. However, the substrate holder 80 may include no wiring storage unit 814.

The bodies 803 and 805 of the front frame 802 and the rear frame 804 are each a member in a substantially plate shape. Openings 803a and 805a for exposing the substrate WF to be held are formed at central parts of the bodies 803 and 805, respectively. The shapes of the openings 803a and 805a each preferably correspond to the shape of a region (plated region) to be plated on the substrate WF. Note that, although the openings 803a and 805a are quadrilateral in the example illustrated in FIG. 2, the present invention is not limited to such an example and the openings 803a and 805a may be each formed in an optional shape such as a circular shape. Although the openings 803a and 805a are formed through both the front frame 802 and the rear frame 804 in the example illustrated in FIG. 2, only the opening 803a may be formed through the front frame 802.

The front frame 802 and the rear frame 804 are clamped by the clampers 820. Although four clampers 820 are illustrated in the example illustrated in FIG. 2, an optional number of clampers 820 may be provided. The front frame 802 and the rear frame 804 are clamped by the clampers 820 in a state (also referred to as a “first state” or a “lock state”) in which the frames can hold the substrate WF by sandwiching (refer to FIG. 3). As an example, the clampers 820 in the present embodiment are configured to be able to form a “semi-lock state” (also referred to as a “second state”). The “semi-lock state” is not the locked state but is a state in which the front frame 802 and the rear frame 804 will not be separated (refer to FIG. 4). In the semi-lock state (second state), the front frame 802 and the rear frame 804 are held further apart from each other than in the lock state (first state). As a specific example, each clamper 820 in an example illustrated in FIGS. 3 and 4 includes a pivotal hook 822, a lock claw 824a, and a semi-lock claw 824b. Note that, as an example, the lock claw 824a and the semi-lock claw 824b may be disposed apart from each other along a pivot axis (axis perpendicular to the sheet in FIGS. 3 and 4) of the hook 822. To facilitate understanding, the semi-lock claw 824b is illustrated with dashed lines in FIGS. 3 and 4. As illustrated in FIG. 3, the lock state in which the substrate WF can be held is achieved by hooking the hook 822 onto the lock claw 824a. As illustrated in FIG. 4, the clamper 820 becomes the semi-lock state by hooking the hook 822 onto the semi-lock claw 824b. Note that the clamper 820 is not limited to the example illustrated in FIGS. 3 and 4 and does not necessarily need to be able to achieve the semi-lock state.

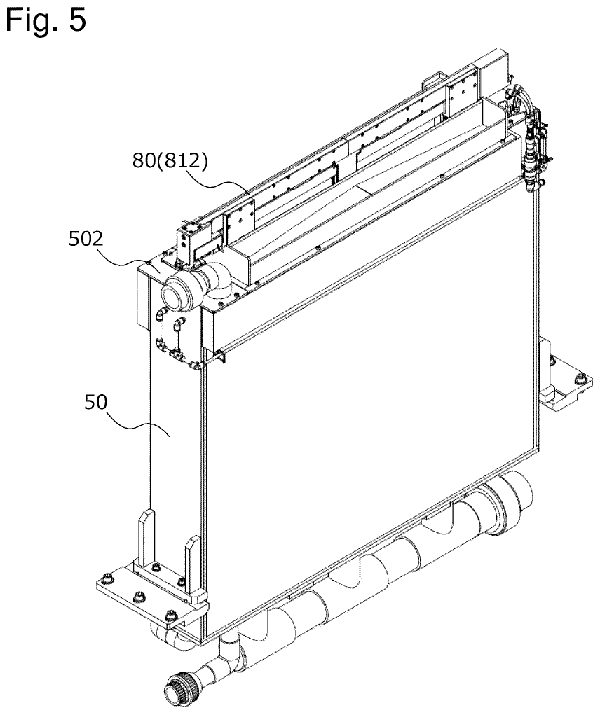

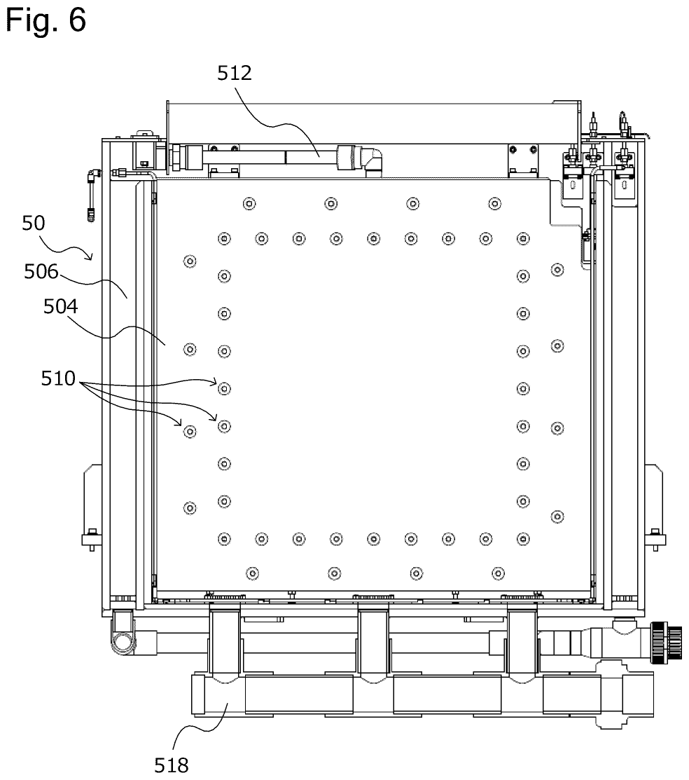

The holder cleaning module and the holder drying module for cleaning and drying such the substrate holder 80 will be described below in detail. FIG. 5 is a perspective view schematically illustrating a configuration overview of the holder cleaning module in the present embodiment, and FIG. 6 is a diagram schematically illustrating the positions of cleaning liquid nozzles in the holder cleaning module illustrated in FIG. 5. Note that, in the illustration of FIG. 5, the substrate holder 80 is housed in the holder cleaning tank 50. The holder cleaning module includes the holder cleaning tank 50 in which the substrate holder 80 can be housed, and is disposed in the processing module 120 (refer to FIG. 1). The holder cleaning tank 50 is configured to house one substrate holder 80 in the present embodiment but may be configured to be able to house two or more substrate holders 80.

The holder cleaning tank 50 includes a holder stage 502 on which the arm unit 812 of the substrate holder 80 is placed to support the substrate holder 80. The holder cleaning tank 50 includes an inner tank 504 with an upper surface that opens to house the substrate holder 80, and an outer tank 506 provided around the inner tank 504 to accumulate cleaning liquid overflowing from an upper edge of the inner tank 504. The holder cleaning tank 50 is provided with a plurality of cleaning liquid nozzles 510 configured to eject cleaning liquid such as deionized water (DIW) toward the substrate holder 80. The plurality of cleaning liquid nozzles 510 are connected to a non-illustrated cleaning liquid supply source through a cleaning liquid pipe 512. In the present embodiment, the plurality of cleaning liquid nozzles 510 are fixed to a nozzle plate disposed along the front frame 802 and the rear frame 804 of the substrate holder 80. Note that the plurality of cleaning liquid nozzles 510 may be disposed with inward or outward tilt to eject cleaning liquid toward the electrical contacts 840 of the substrate holder 80. In addition, a drain pipe 518 is connected to a bottom surface of the holder cleaning tank 50 and configured to be able to discharge cleaning liquid in the holder cleaning tank 50 to the outside.

The holder cleaning tank 50 can house the substrate holder 80 not holding the substrate WF and provide on the substrate holder 80 with the cleaning processing. The substrate holder 80 may be housed in the holder cleaning tank 50 in the semi-lock state described above. In the holder cleaning tank 50, the substrate holder 80 is cleaned by discharging cleaning liquid from the cleaning liquid nozzles 510 toward the substrate holder 80. In this case, the drain pipe 518 may be closed to accumulate cleaning liquid in the holder cleaning tank 50. It may be repeated a plurality of times to fill the inner tank 504 of the holder cleaning tank 50 with cleaning liquid and then open the drain pipe 518 to discharge cleaning liquid in the holder cleaning tank 50. Note that a time taken for the cleaning processing can be shortened by rapidly discharging cleaning liquid from the drain pipe 518, but when cleaning liquid is rapidly discharged, a large amount of cleaning liquid remains in the substrate holder 80 in some cases. Thus, in a process of lastly discharging cleaning liquid from the holder cleaning tank 50, cleaning liquid may be discharged more slowly than in a liquid discharge process so far. When the cleaning processing in the holder cleaning tank 50 has ended, the substrate holder 80 is conveyed to the holder drying tank 60 by the conveyance device 37.

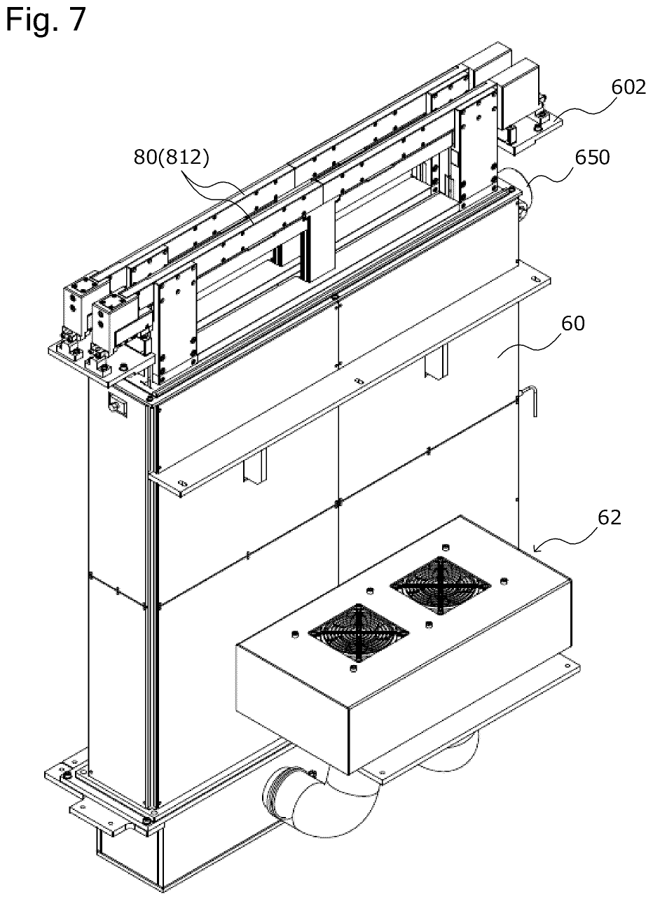

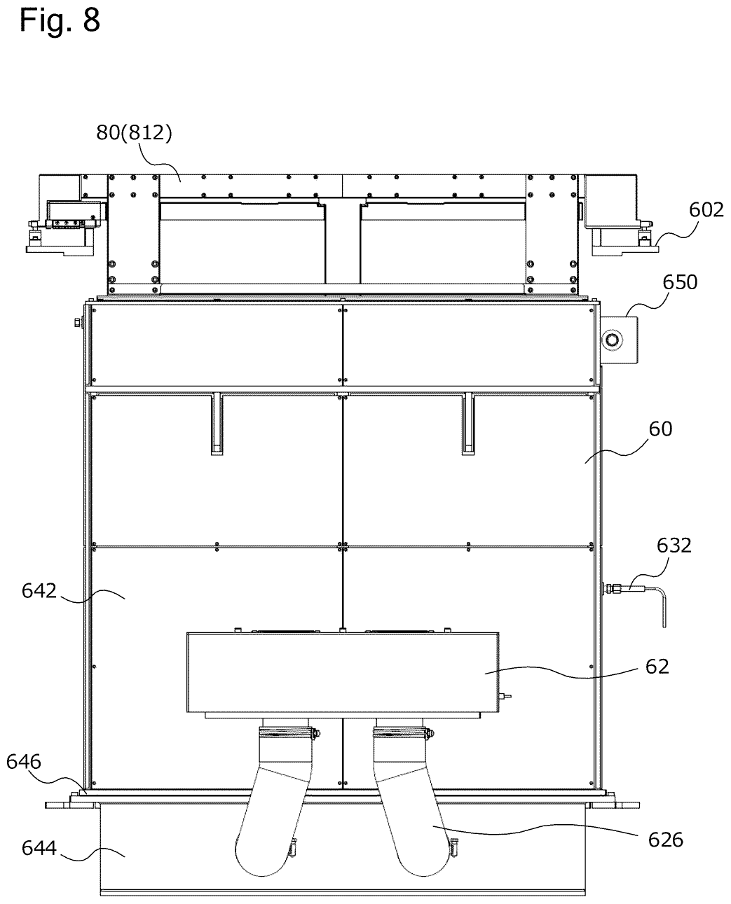

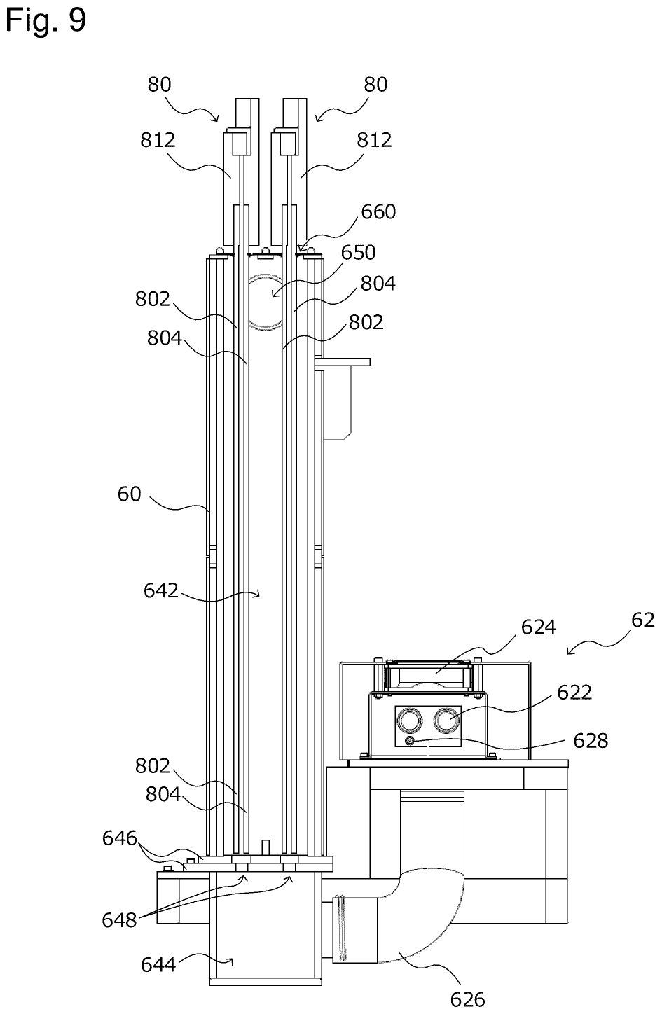

FIG. 7 is a diagram schematically illustrating a schematic configuration of the holder drying module in the present embodiment, FIG. 8 is a front view of the holder drying module illustrated in FIG. 7, and FIG. 9 is a side cross-sectional view of the holder drying module illustrated in FIG. 7. Note that, in the illustration of FIGS. 7 to 9, two substrate holders 80 are housed in the holder drying tank 60. In the present embodiment, the holder drying module includes the holder drying tank 60 in which the substrate holders 80 can be housed and a heater mechanism 62 and is disposed in the processing module 120 (refer to FIG. 1). A drying process of the substrate holders 80 tends to need time as compared to a cleaning process, and thus the holder drying tank 60 preferably can house a larger number of substrate holders 80 than the holder cleaning tank 50. As an example, in the present embodiment, the holder drying tank 60 is configured to house two substrate holders 80. However, the present invention is not limited to such an example, and the holder drying tank 60 may be configured to be able to house one or three or more substrate holders 80. The holder drying tank 60 includes a holder stage 602 on which the arm unit 812 of the substrate holder 80 is placed to support the substrate holder 80.

The heater mechanism 62 is connected to the holder drying tank 60. In the present embodiment, the heater mechanism 62 is disposed beside the holder drying tank 60 in a conveyance direction of the substrate holder 80 by the conveyance device 37. In the present embodiment, a cover 64 is provided to prevent fall of foreign objects such as liquid from the substrate holder 80 or the conveyance device 37 to the heater mechanism 62 (refer to FIG. 1). However, the present invention is not limited to such an example, and the heater mechanism 62 may be provided at an optional place and may be provided with no cover 64.

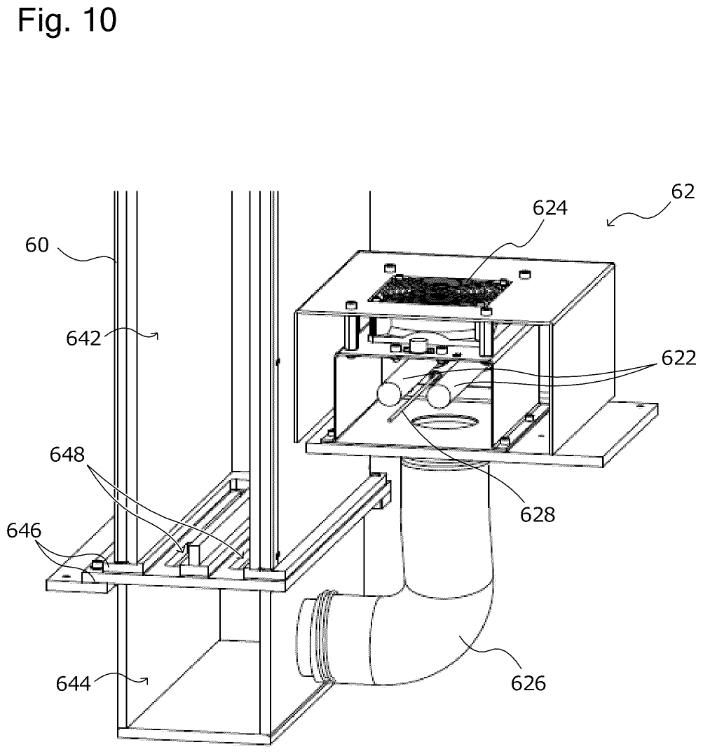

FIG. 10 is a sectional perspective view schematically illustrating the configuration of the holder drying tank 60 and the heater mechanism 62. The heater mechanism 62 includes a heater 622 for heating gas such as air, and a fan 624 for sending the gas heated by the heater 622. The heater mechanism 62 is connected to a lower side (connection chamber 644) of the holder drying tank 60 through an elbow pipe 626. Note that the heater 622 may employ an optional scheme such as a resistance heating scheme. An exhaust duct 650 is connected beside an upper part of the holder drying tank 60.

The holder drying tank 60 in the present embodiment is formed with a vent hole 648 that defines a flow path of gas supplied from the heater mechanism 62. As illustrated in FIGS. 9 and 10, the holder drying tank 60 in the present embodiment is divided, by a plate member 646 extending in a horizontal direction, into a holder chamber 642 at an upper part in which substrate holders 80 are housed and the connection chamber 644 at a lower part to which the heater mechanism 62 is connected. The plate member 646 is formed with the vent hole 648. The vent hole 648 is provided at a position vertically downward between the front frame 802 and the rear frame 804 of the substrate holder 80. Accordingly, gas supplied from the heater mechanism 62 to the holder drying tank 60 flows from the connection chamber 644 to the holder chamber 642 through the vent hole 648 and is directed to between the front frame 802 and the rear frame 804, in particular. Thus, drying of the substrate holder 80 can be promoted by directing gas toward between the front frame 802 and the rear frame 804 where cleaning liquid is likely to remain. Air supplied from the heater mechanism 62 to the holder drying tank 60 is externally discharged from the exhaust duct 650 provided at an upper part of the holder chamber 642. Note that the holder drying tank 60 may include, in place of or in addition to the vent hole 648, a guide body for directing gas to between the front frame 802 and the rear frame 804.

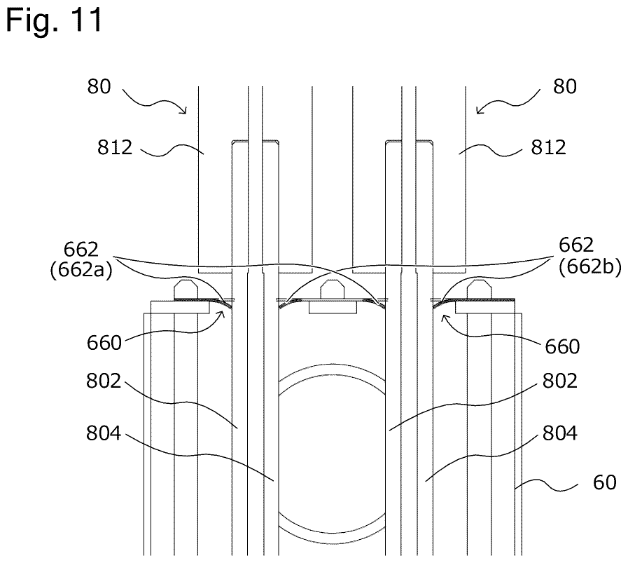

FIG. 11 is a diagram schematically illustrating a first example of a holder insertion port of the holder drying tank 60 in the present embodiment. The upper surface of the holder drying tank 60 is formed with a holder insertion port (opening) 660 for inserting the substrate holder 80. The holder insertion port 660 preferably has dimensions corresponding to the dimensions of the substrate holder 80. In the present embodiment, the shape of the holder insertion port 660 is determined based on the outer shape of the front frame 802 and the rear frame 804 in the semi-lock state. Accordingly, gas leakage from the holder insertion port 660 can be prevented to improve the drying efficiency in the holder drying tank 60. In the example illustrated in FIG. 11, the holder insertion port 660 is provided with an elastic body 662 configured to block the holder insertion port 660 by contacting the front frame 802 and the rear frame 804. The elastic body 662 includes an elastic body 662a that contacts the front frame 802 and an elastic body 662b that contacts the rear frame 804 in the example illustrated in FIG. 11 but may include only one of them. As an example, the gap between the elastic bodies 662a and 662b may be formed smaller than the outer shape dimensions of the front frame 802 and the rear frame 804 in the semi-lock state. It may be configured such that the elastic bodies 662a and 662b deform and contact the front frame 802 and the rear frame 804 to block the holder insertion port 660 when the substrate holder 80 is inserted into the holder insertion port 660. An optional elastic body such as resin or rubber may be employed as the elastic body 662. According to such an example, gas leakage from the holder drying tank 60 can be prevented to improve the drying efficiency.

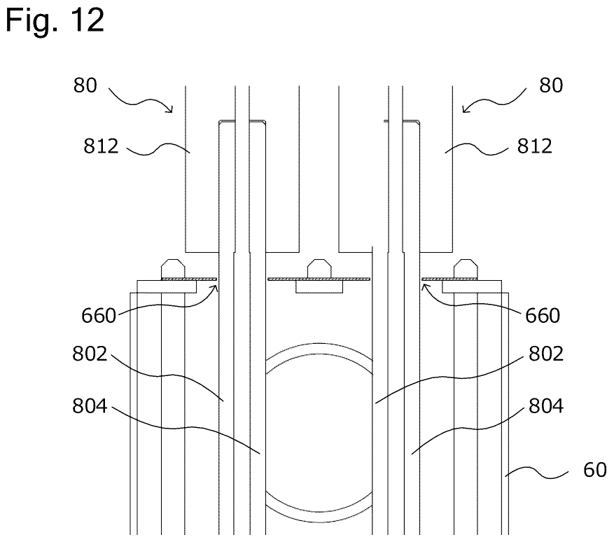

FIG. 12 is a diagram schematically illustrating a second example of the holder insertion port of the holder drying tank 60 in the present embodiment. As in the first example, the shape of the holder insertion port (opening) 660 is determined based on the outer shape of the front frame 802 and the rear frame 804 in the semi-lock state. The holder insertion port 660 as the second example is configured to be blocked by the substrate holder 80 when the substrate holder 80 is housed in the holder drying tank 60. In the present embodiment, the arm unit 812 has a thickness larger than the thickness (length in the right-left direction in FIG. 12) of the front frame 802 and the rear frame 804 and has a shape larger than the holder insertion port 660. The holder insertion port 660 is blocked by the arm unit 812 when the substrate holder 80 is housed in the holder drying tank 60. Note that, in this case, the upper surface of the holder drying tank 60 formed with the holder insertion port 660 may serve as the holder stage 602 for supporting the arm unit 812. According to such an example as well, gas leakage from the holder drying tank 60 can be prevented to improve the drying efficiency. Note that, in the second example, the holder insertion port 660 may be configured to be blocked by another site of the substrate holder 80 instead of the arm unit 812. As an example, the wiring storage unit 814 of the substrate holder 80 may have a thickness larger than the thickness of the bodies 803 and 805 of the front frame 802 and the rear frame 804 and have a shape larger than the holder insertion port 660. The holder insertion port 660 may be blocked by the wiring storage unit 814 when the substrate holder 80 is housed in the holder drying tank 60.

The holder drying module includes a temperature sensor 628 (refer to FIG. 10) for detecting the temperature of air-sending by the heater mechanism 62, and a temperature sensor 632 (refer to FIG. 8) for detecting temperature in the holder drying tank 60. The temperatures detected by the temperature sensors 628 and 632 are transmitted to the controller 175 of the plating apparatus 100 and used for control of the holder drying module by the controller 175.

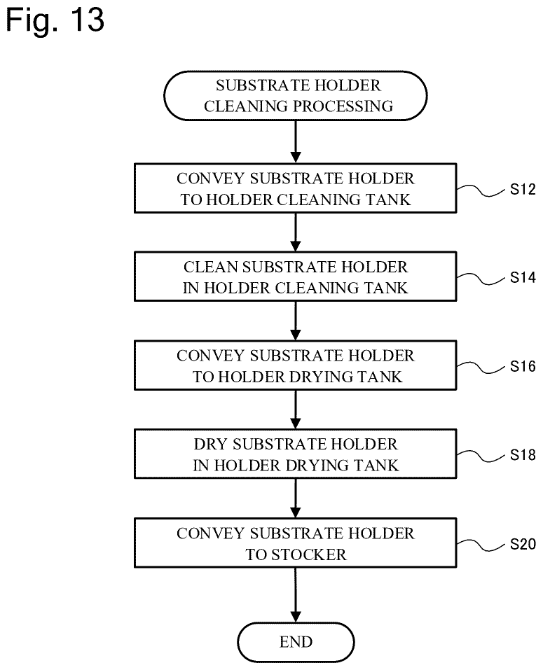

FIG. 13 is a flowchart illustrating an example of the cleaning processing of the substrate holder in the plating apparatus in the present embodiment. As an example, this processing is performed by the controller 175 of the plating apparatus 100. The controller 175 may execute the cleaning processing of the substrate holder at an optional timing. As an example, the controller 175 may provide the substrate holder 80 with the cleaning processing when the substrate holder 80 is used for the plating processing for a predetermined number of times (for example, several times).

In the cleaning processing of the substrate holder, first, the substrate holder 80 not holding the substrate WF is conveyed to the holder cleaning tank 50 by the conveyance device 37 (step S12). In this case, the substrate holder 80 may be in the semi-lock state. As an example, the conveyance device 37 may convey, from the fixing station 29 to the holder cleaning tank 50, the substrate holder 80 from which the substrate WF has been removed at the fixing station 29. Alternatively, the conveyance device 37 may convey the substrate holder 80 stored in the stocker 30 to the holder cleaning tank 50. In this case, the controller 175 may cause the conveyance device 37 to retrieve the substrate holder 80 from the stocker 30 during idle time of the conveyance device 37 and may provide the cleaning processing. In the present embodiment, the substrate holder 80 is conveyed into the holder cleaning tank 50 with the arm unit 812 grasped by the conveyance device 37 and is housed in the holder cleaning tank 50 with the arm unit 812 placed on the holder stage 502. After the substrate holder 80 is housed in the holder cleaning tank 50, cleaning of the substrate holder 80 is performed in the holder cleaning tank 50 (step S14).

When the cleaning of the substrate holder 80 in the holder cleaning tank 50 has ended, the conveyance device 37 conveys the substrate holder 80 from the holder cleaning tank 50 to the holder drying tank 60 (step S16). In the present embodiment, the substrate holder 80 is conveyed from the holder cleaning tank 50 to the holder drying tank 60 by the conveyance device 37 with the arm unit 812 grasped and is housed in the holder drying tank 60 with the arm unit 812 placed on the holder stage 602. After the substrate holder 80 is housed in the holder drying tank 60, drying of the substrate holder 80 is performed in the holder drying tank 60 (step S18).

Then, when the drying of the substrate holder 80 in the holder drying tank 60 has ended, the conveyance device 37 conveys the substrate holder 80 from the holder drying tank 60 to the stocker 30 (step S20), which ends the cleaning processing of the substrate holder 80. Note that the conveyance device 37 may convey the substrate holder 80 to the fixing station 29 in place of the stocker 30 as necessary.

As described above, the plating apparatus 100 in the present embodiment includes the holder cleaning tank 50 for cleaning the substrate holder 80 when the substrate holder 80 is not holding the substrate WF, and the holder drying tank 60 for drying the cleaned substrate holder 80. With this configuration, it is possible to dry the substrate holder 80 in the holder drying tank 60 and remove cleaning liquid remaining after cleaning of the substrate holder 80. Since the holder cleaning tank 50 and the holder drying tank 60 are separately provided, cleaning liquid having adhered to the tank in the cleaning process does not need to be removed in the drying process, and thus the drying efficiency can be improved. Moreover, since the holder cleaning tank 50 and the holder drying tank 60 are separately provided, it is possible to prevent cleaning liquid scattering to a mechanism in the holder drying tank 60, such as the heater mechanism 62, in the cleaning process, thereby achieving device simplification.

The present invention can be written in aspects as follows.

[Aspect 1] According to Aspect 1, a plating apparatus is proposed, and the plating apparatus includes a substrate holder configured to hold a substrate and including an electrical contact for supplying power to the substrate, a holder cleaning tank for cleaning the substrate holder when the substrate holder is not holding the substrate, a holder drying tank for drying the substrate holder cleaned in the holder cleaning tank, and a conveyance device for conveying the substrate holder between the holder cleaning tank and the holder drying tank. According to Aspect 1, since the holder drying tank for drying the substrate holder cleaned in the holder cleaning tank is provided, it is possible to remove cleaning liquid remaining after cleaning of the substrate holder.

[Aspect 2] According to Aspect 2, in Aspect 1, a heater mechanism including a fan and a heater and configured to supply gas heated by the heater to the holder drying tank is further included.

[Aspect 3] According to Aspect 3, in Aspect 2, the substrate holder includes a front frame and a rear frame for holding the substrate by sandwiching the substrate, and the heater mechanism is configured to supply gas between the front frame and the rear frame. According to Aspect 3, it is possible to further remove cleaning liquid remaining after cleaning of the substrate holder.

[Aspect 4] According to Aspect 4, in Aspect 2 or 3, the drying holder includes a vent hole that defines a flow path of gas supplied from the heater mechanism, and the vent hole is positioned vertically downward between the front frame and the rear frame when the substrate holder is housed in the drying holder. According to Aspect 4, it is possible to further remove cleaning liquid remaining after cleaning of the substrate holder.

[Aspect 5] According to Aspect 5, in any one of Aspects 1 to 4, the substrate holder includes a front frame and a rear frame for holding the substrate by sandwiching the substrate, and an arm unit or a wiring storage unit that is connected to at least one of the front frame and the rear frame, the holder drying tank includes an opening with dimensions that allow insertion of the front frame and the rear frame, and the opening is configured to be blocked by the arm unit or the wiring storage unit when the substrate holder is housed in the holder drying tank. According to Aspect 5, it is possible to improve the drying efficiency in the holder drying tank.

[Aspect 6] According to Aspect 6, in any one of Aspects 1 to 5, the substrate holder includes a front frame and a rear frame for holding the substrate by sandwiching the substrate, and the holder drying tank includes an opening with dimensions that allow insertion of the front frame and the rear frame, and an elastic body configured to block the opening by contacting at least one of the front frame and the rear frame when the substrate holder is housed in the holder drying tank. According to Aspect 6, it is possible to improve the drying efficiency in the holder drying tank.

[Aspect 7] According to Aspect 7, in any one of Aspects 1 to 6, the substrate holder includes a front frame, a rear frame, and a clamper for clamping the front frame and the rear frame, the clamper is configured to be able to hold the front frame and the rear frame in a first state for sandwiching the substrate by the front frame and the rear frame and in a second state in which distance between the front frame and the rear frame is longer than in the first state, and the conveyance device is configured to convey the substrate holder held in the second state to the holder cleaning tank and the holder drying tank. According to Aspect 7, it is possible to further remove cleaning liquid remaining after cleaning of the substrate holder.

[Aspect 8] According to Aspect 8, in any one of Aspects 1 to 7, a stocker capable of storing a plurality of the substrate holders is included, and the conveyance device is configured to convey the substrate holders stored in the stocker to the holder cleaning tank and the holder drying tank.

[Aspect 9] According to Aspect 9, in any one of Aspects 1 to 8, a plating tank is included, the substrate holder includes an arm unit placed on a holder stage of the plating tank, the conveyance device is configured to convey the substrate holder by grasping the arm unit, and the holder cleaning tank and the holder drying tank each include a holder stage for supporting the substrate holder by placing the arm unit of the substrate holder. According to Aspect 9, the arm unit placed on the holder stage of the plating tank can be used to support the substrate holder to the holder cleaning tank and the holder drying tank.

[Aspect 10] According to Aspect 10, a cleaning method for cleaning a substrate holder including an electrical contact for supplying power to a substrate in a plating apparatus is proposed, and the cleaning method includes a process of conveying the substrate holder holding no substrate to a cleaning tank by a conveyance device, a process of cleaning the substrate holder in the cleaning tank, a process of conveying the cleaned substrate holder from the cleaning tank to a drying tank, and a process of drying the substrate holder in the drying tank. According to Aspect 10, the substrate holder cleaned in the holder cleaning tank can be dried in the holder drying tank, and it is possible to remove cleaning liquid remaining after cleaning of the substrate holder.

The embodiment of the present invention is described above. The above-described embodiment of the invention is provided to facilitate understanding of the present invention and does not limit the present invention. Needless to say, the present invention may be changed and modified without departing from the scope of the invention, and equivalents are also included in the present invention. Also in a range in which at least some of the problems described above can be solved or a range in which at least some of the effects are exhibited, any combination of the embodiments and the modification is possible, and any combination of constituent components described in the claims and the specification, or their omission, may be possible. Moreover, not only a semiconductor wafer but also a glass substrate or a printed circuit board may be used as a substrate to be plated.

### REFERENCE SIGNS LIST

WF . . . substrate
30 . . . stocker
32 . . . pre-wet tank
36 . . . pre-soak tank
37 . . . conveyance device
40, 40A to 40C . . . plating tank
42, 42A to 42C . . . rinse tank
44 . . . blow tank
50 . . . holder cleaning tank
60 . . . holder drying tank
62 . . . heater mechanism
64 . . . cover
80 . . . substrate holder
100 . . . plating apparatus
175 . . . controller
502 . . . holder stage
510 . . . cleaning liquid nozzle
602 . . . holder stage
622 . . . heater
624 . . . fan
648 . . . vent hole
650 . . . exhaust duct
660 . . . holder insertion port (opening)
662 . . . elastic body
802 . . . front frame
804 . . . rear frame
812 . . . arm unit
814 . . . wiring storage unit
820 . . . clamper
822 . . . hook
824a . . . lock claw
824b . . . semi-lock claw
840 . . . electrical contact

1. A plating apparatus comprising:
a substrate holder configured to hold a substrate and including an electrical contact for supplying power to the substrate;
a holder cleaning tank for cleaning the substrate holder when the substrate holder is not holding the substrate;
a holder drying tank for drying the substrate holder cleaned in the holder cleaning tank; and
a conveyance device for conveying the substrate holder between the holder cleaning tank and the holder drying tank.

2. The plating apparatus according to claim 1, comprising a heater mechanism including a fan and a heater and configured to supply gas heated by the heater to the holder drying tank.

3. The plating apparatus according to claim 2, wherein
the substrate holder includes a front frame and a rear frame for holding the substrate by sandwiching the substrate, and
the heater mechanism is configured to supply gas between the front frame and the rear frame.

4. The plating apparatus according to claim 3, wherein the holder drying tank includes a vent hole that defines a flow path of gas supplied from the heater mechanism, and the vent hole is positioned vertically downward between the front frame and the rear frame when the substrate holder is housed in the holder drying tank.

5. The plating apparatus according to claim 1, wherein
the substrate holder includes
a front frame and a rear frame for holding the substrate by sandwiching the substrate, and
an arm unit or a wiring storage unit that is connected to at least one of the front frame and the rear frame, and
the holder drying tank includes an opening with dimensions that allow insertion of the front frame and the rear frame, and the opening is configured to be blocked by the arm unit or the wiring storage unit when the substrate holder is housed in the holder drying tank.

6. The plating apparatus according to claim 1, wherein
the substrate holder includes a front frame and a rear frame for holding the substrate by sandwiching the substrate, and
the holder drying tank includes
an opening with dimensions that allow insertion of the front frame and the rear frame, and
an elastic body configured to block the opening by contacting at least one of the front frame and the rear frame when the substrate holder is housed in the holder drying tank.

7. The plating apparatus according to claim 1, wherein
the substrate holder includes
a front frame,
a rear frame, and
a clamper for clamping the front frame and the rear frame,
the clamper is configured to be able to hold the front frame and the rear frame in a first state for sandwiching the substrate by the front frame and the rear frame and in a second state in which distance between the front frame and the rear frame is longer than in the first state, and
the conveyance device is configured to convey the substrate holder held in the second state to the holder cleaning tank and the holder drying tank.

8. The plating apparatus according to claim 1, comprising a stocker capable of storing a plurality of the substrate holders, wherein the conveyance device is configured to convey the substrate holders stored in the stocker to the holder cleaning tank and the holder drying tank.

9. The plating apparatus according to claim 1, comprising a plating tank, wherein
the substrate holder includes an arm unit placed on a holder stage of the plating tank,
the conveyance device is configured to convey the substrate holder by grasping the arm unit, and
the holder cleaning tank and the holder drying tank each include a holder stage for supporting the substrate holder by placing the arm unit of the substrate holder.

10. A cleaning method for cleaning a substrate holder including an electrical contact for supplying power to a substrate in a plating apparatus, the cleaning method comprising:
a process of conveying the substrate holder holding no substrate to a cleaning tank by a conveyance device;
a process of cleaning the substrate holder in the cleaning tank;
a process of conveying the cleaned substrate holder from the cleaning tank to a drying tank; and
a process of drying the substrate holder in the drying tank.
